(19) United States
(12) Patent Application Publication
(10) Pub. No.: US 2024/0372321 A1
(43) Pub. Date: Nov. 7, 2024

(54) OPTICAL APPARATUS

(71) Applicants: Thomas JESSENIG, Eindhoven (NL); Radoslaw Marcin GANCARZ, Eindhoven (NL); Pierre-Yves TALOUD, Eindhoven (NL); Javier Miguel SANCHEZ, Eindhoven (NL)

(72) Inventors: Thomas JESSENIG, Eindhoven (NL); Radoslaw Marcin GANCARZ, Eindhoven (NL); Pierre-Yves TALOUD, Eindhoven (NL); Javier Miguel SANCHEZ, Eindhoven (NL)

(21) Appl. No.: 18/290,664

(22) PCT Filed: Mar. 25, 2022
(86) PCT No.: PCT/EP2022/057984

§ 371 Date: Jan. 19, 2024

(30) Foreign Application Priority Data
Jul. 27, 2021 (GB) 2110764.4

(51) Int. Cl. H01S 5/062; H01S 5/183

(52) U.S. Cl. CPC H01S 5/062; H01S 5/183

(57) ABSTRACT

An optical apparatus comprising: a light-emitting device coupled to a controllable voltage supply configured to provide a supply voltage to the light-emitting device; a temperature sensor arranged to sense a temperature of the light-emitting device; a driver die comprising a driver circuit for driving the light-emitting device; and a control module configured to: receive a voltage at the output of the light-emitting device; determine a target voltage that is to be provided at the output of the light-emitting device, wherein the control module is configured to determine the target voltage based on said temperature; and output a control signal to control the output of the light-emitting device to be at the target voltage in dependence on the voltage at the output of the light-emitting device.

### TECHNICAL FIELD

This disclosure relates to an optical apparatus for controlling the output voltage of a light-emitting device.

### BACKGROUND

There is a great demand for optical (e.g. laser) modules for 3D applications, mainly using time of flight (ToF) technology. These typically include driver circuitry that host some extra functionality as just simply a driving current stage.

One of the key performance indicators of such optical modules, together with the range, is the power consumption. Typically, as these systems are integrated on portable devices (mobile phones, AR glasses, tablets, drones, etc.), the power has to be minimized and the efficiency of the modules maximized.

A known driver circuit 100 for driving a light-emitting device, e.g. a vertical cavity surface emitting laser (VCSEL) is shown in FIG. 1. The known driver circuit 100 comprises a fixed laser diode driver voltage supply (LDDVDD) 102, a capacitor 104, the light-emitting device 106 and a controllable current source 108.

Sometimes, these optical modules, use so called ‘multi junction’ light-emitting devices, where several junctions are piled up during epitaxy to achieve higher peak powers and power conversion efficiencies (PCE).

### SUMMARY

The inventors have identified that known solutions apply a fixed laser diode driver voltage supply (LDDVDD) for the full temperature range operation of the light-emitting device with no regulation of the applied voltage.

This is problematic as the voltage drop on both the light-emitting device and the controllable current source (e.g. a MOSFET) increase at lower temperatures.

Especially for solutions a light-emitting device comprising more than a single junction is used (‘n’ junctions), a large margin for LDDVDD has to be provided, as the operating voltage of the light-emitting device changes with temperature proportionally to ‘n’ (the number of junctions).

Example data 200 of the operating voltage of 5 different devices of a 5 junction VCSEL structure emitting light at 5 different wavelengths is shown in FIG. 2 at temperatures both less than, and greater than, room temperature 202.

As can be seen from the higher end of the operation temperature range (80° C.) to the lower end of the operation temperature range (−20° C.), there may be variations of more than 3V. So typically, a voltage margin larger than 3V is added to the supply to account for this variation.

However, at currents flowing of around 15 A, having this ‘voltage margin’ creates a loss of 3V·15 A=45 W instantaneous power dissipated on the laser driver channel. For a duty cycle of 10%, this means 4.5 W dissipated on the laser driver.

For consumer electronics applications, where the battery life shall be maximized, it is desirable to minimize any power loss like this.

According to one aspect of the present disclosure there is provided an optical apparatus comprising:
a light-emitting device coupled to a controllable voltage supply configured to provide a supply voltage to the light-emitting device;
a temperature sensor arranged to sense a temperature of the light-emitting device;
a driver die comprising a driver circuit for driving the light-emitting device; and
a control module configured to:
   receive a voltage at the output of the light-emitting device;
   determine a target voltage that is to be provided at the output of the light-emitting device, wherein the control module is configured to determine the target voltage based on said temperature; and
   output a control signal to control the output of the light-emitting device to be at the target voltage in dependence on the voltage at the output of the light-emitting device.

The control module may be configured to: compare the voltage at the output of the light-emitting device to the target voltage; and output the control signal to the controllable voltage supply to control the supply voltage in dependence on the comparison.

If the voltage at the output of the light-emitting device is greater than the target voltage, the control module may be configured to output the control signal to the controllable voltage supply to decrease the supply voltage. If the voltage at the output of the light-emitting device is less than the target voltage, the control module may be configured to output the control signal to the controllable voltage supply to increase the supply voltage.

The target voltage may minimize the power loss of the driver die.

Thus some embodiments of the present disclosure enable the power loss on the driver die to be minimized by adjusting the controllable voltage supply throughout the full temperature range.

In some embodiments, the control module may be configured to: compare the voltage at the output of the light-emitting device to the target voltage; and output the control signal to a current source of the driver circuit, to control an amount of current flowing through the light-emitting device in dependence on the comparison.

The driver die may comprise a controllable current source and if the voltage at the output of the light-emitting device is greater than the target voltage, the control module may be configured to output the control signal to the controllable current source increase current flowing through the light-emitting device. If the voltage at the output of the light-emitting device is less than the target voltage, the control module may be configured to output the control signal to the controllable current source to decrease current flowing through the light-emitting device.

Thus some embodiments of the present disclosure enable the optical power output of the light-emitting device to be maximized throughout the full temperature range.

The control module may be configured to: retrieve from memory a voltage-current curve associated with the temperature; use the voltage at the output of the light-emitting device and the voltage-current curve to determine the current flowing through the light-emitting device; retrieve from memory a power-current curve associated with the temperature; use the current flowing through the light-emitting device and the power-current curve to determine the optical power of light emitted by the light-emitting device; and control a controllable current source of the driver die to maintain the optical power of light emitted by the light-emitting device constant.

Thus some embodiments of the present disclosure enable the optical power to be maintained constant without the need of an external photodiode, throughout the full temperature range.

The light-emitting device may be integrated into the driver die. Alternatively, the light-emitting device may be external to the driver die (e.g. mounted to an upper surface of the driver die).

The control module may be external to the driver die. Alternatively, the control module may be integrated into the driver die.

The controllable voltage supply may be integrated into the driver die. Alternatively, the controllable voltage supply may be external to the driver die.

The driver die may comprise a voltage readout circuit coupled to the light-emitting device, the voltage readout circuit configured to detect and supply the voltage at the output of the light-emitting device to the control module.

The light-emitting device may comprise a vertical cavity surface emitting laser.

According to one aspect of the present disclosure there is provided an optoelectronic module comprising:
the apparatus according to any of the embodiments described herein;
a substrate, wherein the driver die is mounted to an upper surface of the substrate;
a spacer mounted to the upper surface of the substrate, the spacer laterally surrounding the light-emitting device; and
an optical element mounted to the spacer, the optical element transparent to light emitted by the light-emitting device.

These and other aspects will be apparent from the embodiments described in the following. The scope of the present disclosure is not intended to be limited by this summary nor to implementations that necessarily solve any or all of the disadvantages noted.

### BRIEF DESCRIPTION OF THE DRAWINGS

Some embodiments of the disclosure will now be described by way of example only and with reference to the accompanying drawings, in which:

FIG. 1 illustrates a known driver circuit for driving a light-emitting device;

FIG. 2 illustrates the temperature dependency of the operating voltage of a light-emitting device;

FIG. 3 illustrates an optical apparatus according to an embodiment of the present disclosure;

FIG. 4 is a flow chart of a process to minimize power loss of the light-emitting device;

FIG. 5 is a flow chart of a process to maximise power output of the light-emitting device during which the temperature of the light-emitting device is sensed;

FIG. 6 is a flow chart of a process to maximise power output of the light-emitting device without sensing the temperature of the light-emitting device;

FIG. 7 is a flow chart of a process to maintain the optical power of light emitted by the light-emitting device constant;

FIG. 8 illustrates an optical apparatus according to a further embodiment of the present disclosure;

FIG. 9 illustrates an optical apparatus according to a further embodiment of the present disclosure;

FIG. 10a is an example voltage readout circuit that may be used in the optical apparatus.

FIG. 10b illustrates waveforms associated with the example voltage readout circuit shown in FIG. 10a; and

FIG. 11 illustrates an optoelectronic module.

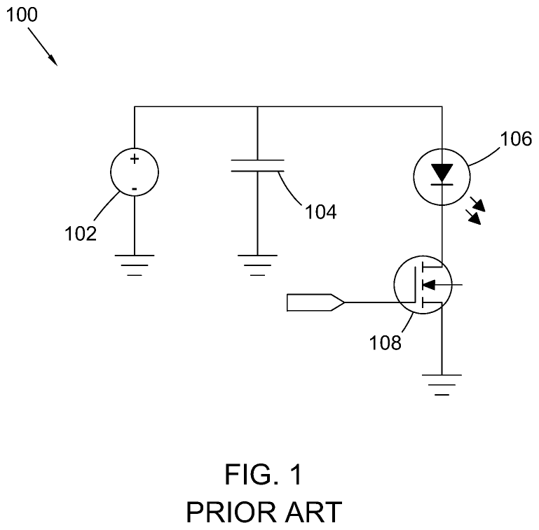

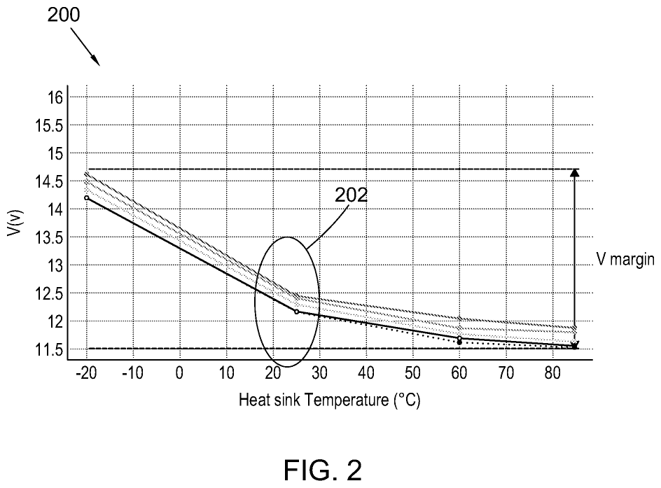

### DETAILED DESCRIPTION

Specific embodiments will now be described with reference to the drawings.

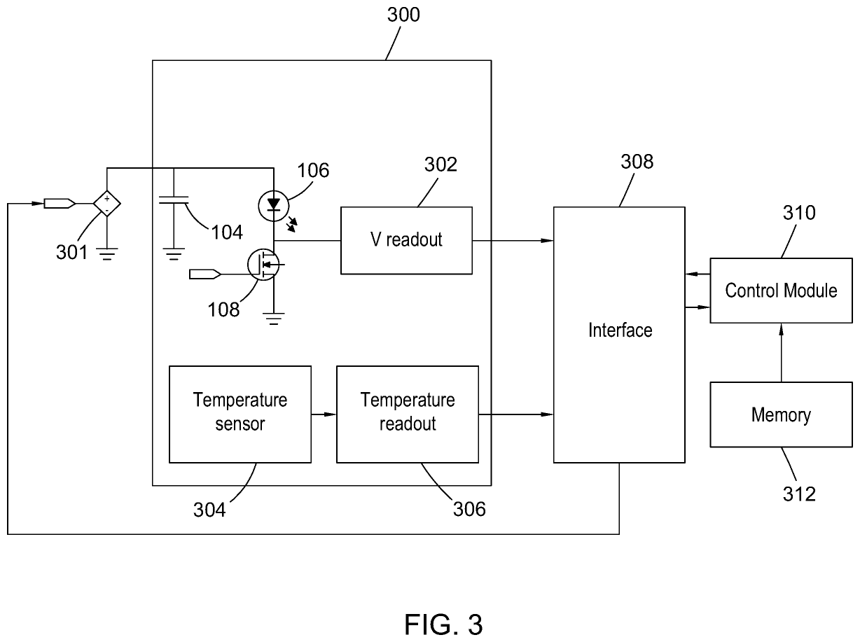

FIG. 3 illustrates a driver die (e.g., an integrated circuit chip) 300 which may be an application-specific integrated circuit (ASIC). The driver die 300 is mounted to a substrate (not shown in FIG. 3) which may be a printed circuit board (PCB), a laminate substrate, a lead-frame substrate or the like. The driver die 300 may be mounted to the substrate by gluing (e.g. using a die attach film or a liquid adhesive) or soldering.

The driver die is coupled to a controllable voltage source 301. The controllable voltage source 301 may comprise a DC-to-DC converter. In the example implementation shown in FIG. 3, the controllable voltage source 301 is external to the driver die 300.

The driver die 300 comprises components of a driver circuit including a capacitor 104, light-emitting device 106 (an optical emitter), and a controllable current source 108.

The light-emitting device 106 may comprise one or more light emitting diodes (LEDs), lasers, or other devices. In some embodiments, the light-emitting device 106 comprises one or more vertical-cavity surface-emitting lasers (VCSELs). The VCSEL may be a multi-junction device having n junctions. The light-emitting device 106 may be configured to emit visible light and/or invisible radiation, such as infrared or near-infrared radiation.

In the embodiments described herein, the light-emitting device 106 may be (i) integrated into the driver die; (ii) mounted to a surface of the driver die; (iii) external to the driver die e.g. mounted to the same substrate to which the driver die is mounted.

The light-emitting device 106 may mounted to the upper surface of the driver die. Various different methods for mounting the light-emitting device 106 to the driver die may be used. The light-emitting device 106 may be mounted to the driver die by gluing with a conductive adhesive or soldering.

As shown in FIG. 3, the driver die 300 comprises a voltage readout circuit 302 coupled to the light-emitting device 106. The voltage readout circuit 302 is configured to detect the voltage at the output of the light-emitting device 106. The voltage at the output of the light-emitting device 106 corresponds to the voltage supplied by the controllable voltage source 301 minus the operating voltage of the light-emitting device 106 (i.e. the voltage dropped across the light-emitting device 106), and is referred herein to a voltage margin.

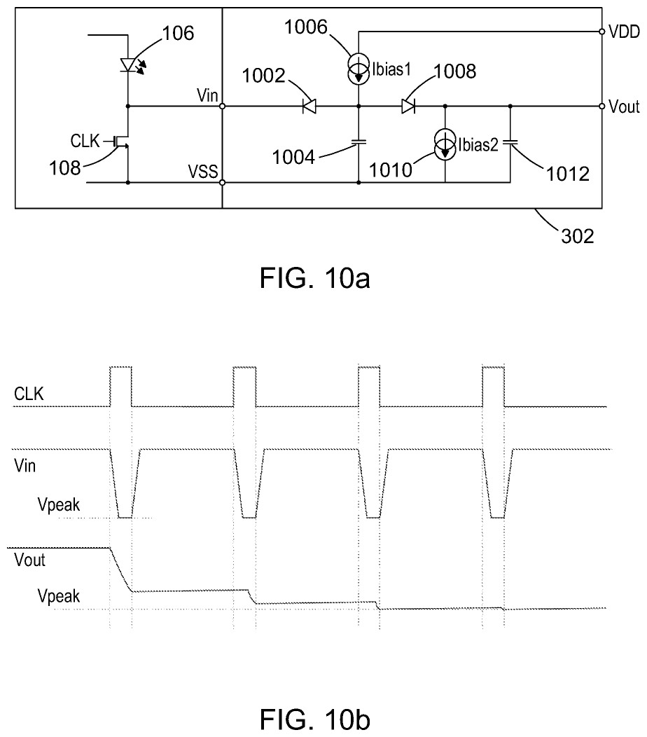

The voltage readout circuit 302 is configured to supply the voltage margin to a control module 310. The voltage readout circuit 302 may be implemented in various ways. An example voltage readout circuit 302 is described below with reference to FIGS. 10a and 10b.

In some embodiments, a temperature sensor 304 is used to sense a temperature of the light-emitting device 106. The temperature sensor 304 may be integrated into the driver die. Alternatively, the temperature sensor 304 may be external to the driver die. The light-emitting device 106 may be mounted to a heatsink formed of a heat-conducting material and the temperature sensor 304 may be mounted to this heatsink and detects the temperature of the heatsink to sense the temperature of the light-emitting device 106. In other implementations, the temperature sensor 304 is arranged to sense the temperature of the environment in the vicinity of the light-emitting device 106.

In embodiments in which a temperature sensor 304 is used to sense a temperature of the light-emitting device 106, a temperature readout circuit 306 is used to supply the temperature of the light-emitting device 106 sensed by the temperature sensor 304 to the control module 310. The temperature readout circuit 306 may comprise an analogue-to-voltage converter that is configured to receive an analogue voltage that is indicative of the temperature of the light-emitting device 106 and convert this to a digital voltage for processing by the control module 310. Such temperature readout circuits are known to persons skilled in the art and are therefore not discussed herein.

The voltage readout circuit 302 may supply the voltage margin to a control module 310 via an interface 308. In embodiments in which a temperature sensor 304 is used to sense a temperature of the light-emitting device 106, the temperature readout circuit 306 may supply the temperature of the light-emitting device 106 to a control module 310 via the interface 308.

The interface 308 may be any communication link to enable the voltage readout circuit 302 and the temperature readout circuit 306 to send data to, and receive data from, the control module 310. For example the interface 308 may be a serial communication bus such as an I²C (Inter-Integrated Circuit) bus.

As will be described in more detail below, the control module 310 receives the voltage margin and is configured to determine a target voltage that is to be provided at the output of the light-emitting device. The control module 310 is further configured to output a control signal to control the output of the light-emitting device to be at the target voltage.

The control module 310 may supply a control signal to the controllable voltage source 301 via the interface 308 to control the voltage supplied by the controllable voltage source 301. Alternatively or additionally, the control module 310 may supply a control signal to the controllable voltage source 301 via the interface 308 to the controllable current source 108. The controllable current source 108 may be a transistor (e.g. a field effect transistor such as a MOSFET) and the control module 310 may supply the control signal to a gate of the transistor to thereby control the gate voltage.

The control module 310 may be coupled to a memory 312. In the example implementation shown in FIG. 3, the control module 310 and memory 312 is external to the driver die 300. The functionality of the control module 310 described herein may be implemented in code (software) stored on a memory (e.g. memory 312) comprising one or more storage media, and arranged for execution on a processor comprising one or more processing units. The storage media may be integrated into and/or separate from the control module 310. The code is configured so as when fetched from the memory and executed on the processor to perform operations in line with embodiments discussed herein. Alternatively it is not excluded that some or all of the functionality of the control module 310 is implemented in dedicated hardware circuitry, or configurable hardware circuitry like an FPGA.

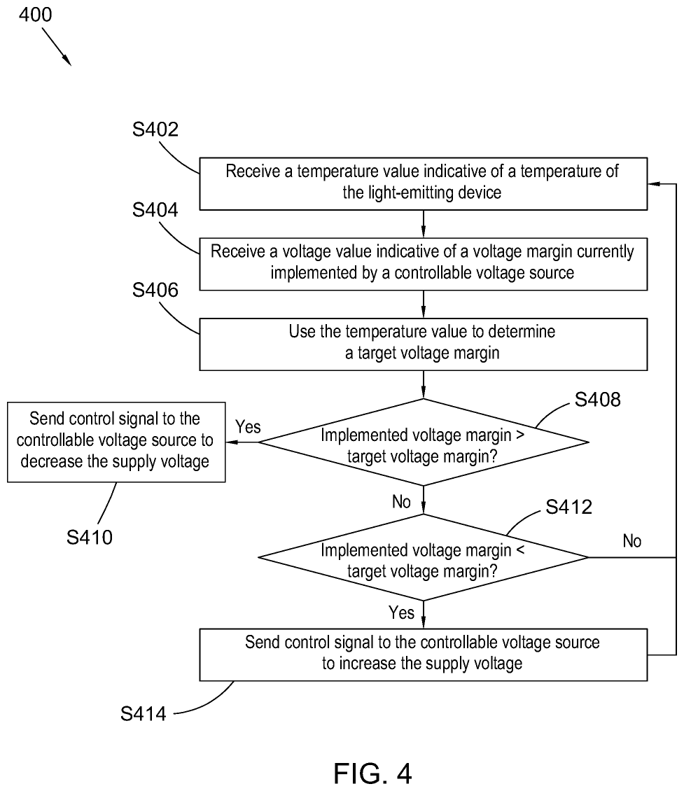

Reference is now made to FIG. 4 which is a flow chart of an example process 400 that may be implemented by the control module 310 to minimize power loss of the driver die 300.

Prior to the process 400 being performed a pulse of light may be emitted by the light-emitting device 106.

At step S402, the control module 310 receives a temperature value indicative of a temperature of the light-emitting device 106 that has been sensed by the temperature sensor 304. The control module 310 receives the temperature value from the temperature readout circuit 306 via the interface 308.

At step S404, the control module 310 receives a voltage at the output of the light-emitting device 106. That is, the control module 310 receives a voltage indicative of a voltage margin currently implemented by the controllable voltage source 301. The control module 310 receives the voltage margin from the voltage readout circuit 302 via the interface 308.

At step S406, the control module 310 uses the temperature value to determine a target voltage margin i.e. a target voltage for the output of the light-emitting device 106, to minimize power loss inside the driver die. This can be implemented in a number of different ways.

In one example, at step S406 the control module 310 may determine the target voltage margin by querying a look up table stored in memory 312. The look up table storing a plurality of target voltage margins that minimize power loss, each of the plurality of target voltage margins associated with a respective temperature value. Thus, by querying the look up table with the sensed temperature a target voltage margin to minimize power loss at that temperature can be retrieved by the control module 310.

In another example, at step S406 the control module 310 may calculate the target voltage margin that minimizes power loss using a formula stored in the memory 312 which uses the sensed temperature as an input.

In another example, at step S406 the control module 310 may use the temperature value to trigger an external circuit that regulates the applied voltage to a configured value under the control of the control module 310 to minimize power loss inside the driver die.

At step S408, the control module 310 evaluates the voltage margin received from the voltage readout circuit 302. In particular, the control module 310 compares the voltage margin received from the voltage readout circuit 302 at step S404, to the target voltage margin determined at step S406, and controls controllable voltage supply 301 in dependence on the comparison.

If the control module 310 determines at step S408 that the voltage margin received from the voltage readout circuit 302 is greater than the target voltage margin (i.e. larger than needed), the process proceeds to step S410 where the control module 310 sends a control signal, via the interface 308, to the controllable voltage supply 301 to decrease the supply voltage. This results in the voltage margin (the voltage at the output of the light-emitting device 106) reducing and thus the power dissipated at the driver die is reduced.

If the control module 310 determines at step S412 that the voltage margin received from the voltage readout circuit 302 is less than the target voltage margin (i.e. lower than needed), the process proceeds to step S414 where the control module 310 sends a control signal, via the interface 308, to the controllable voltage supply 301 to increase the supply voltage. This results in the voltage margin (the voltage at the output of the light-emitting device 106) increasing. The control module 310 may then additionally flag this event (either in a register or via an external communication) to indicate that the emitted pulse may have been compromised and may not have enough power.

After the next pulse request is received by the driver die 300, and the next pulse of light is emitted by the light-emitting device 106, the process 400 then loops back to step S402.

In cases where the readout of the voltage at the output of the light-emitting device 106 is slower than a single pulse, a cycle of the above process 400 could be implemented to run for a plurality of pulses, or as long as the voltage readout circuit 302 needs to determine the voltage margin properly.

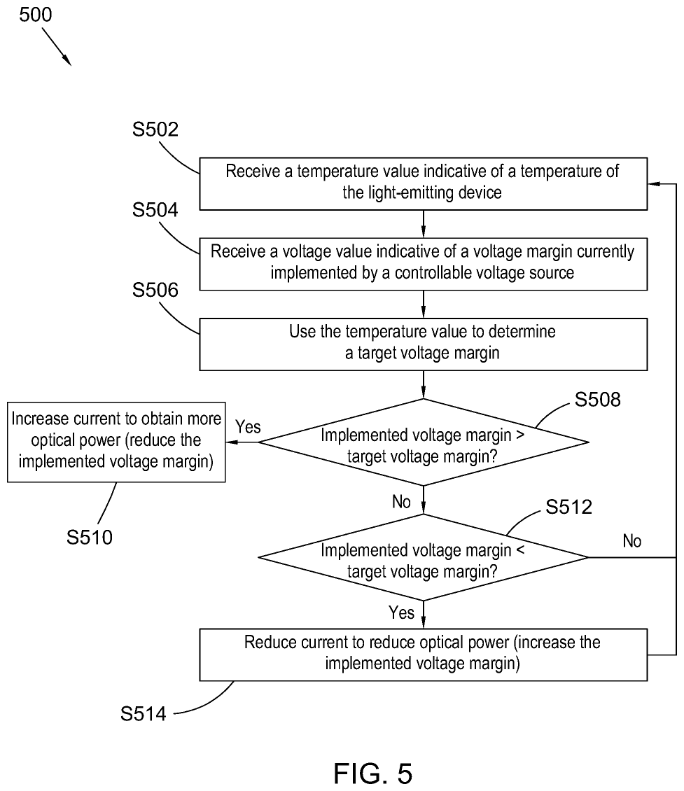

Reference is now made to FIG. 5 which is a flow chart of an example process 500 that may be implemented by the control module 310 to maximise the optical power output of the light-emitting device.

Prior to the process 500 being performed a pulse of light may be emitted by the light-emitting device 106.

At step S502, the control module 310 receives a temperature value indicative of a temperature of the light-emitting device 106 that has been sensed by the temperature sensor 304. The control module 310 receives the temperature value from the temperature readout circuit 306 via the interface 308.

At step S504, the control module 310 receives a voltage at the output of the light-emitting device 106. That is, the control module 310 receives a voltage indicative of a voltage margin currently implemented by the controllable voltage source 301. The control module 310 receives the voltage margin from the voltage readout circuit 302 via the interface 308.

At step S506, the control module 310 uses the temperature value to determine a target voltage margin i.e. a target voltage for the output of the light-emitting device 106 to maximize the optical power output of the light-emitting device 106. This can be implemented in a number of different ways.

In one example, at step S506 the control module 310 may determine the target voltage margin by querying a look up table stored in memory 312. The look up table storing a plurality of target voltage margins that maximizes the optical power output of the light-emitting device 106, each of the plurality of target voltage margins associated with a respective temperature value. Thus, by querying the look up table with the sensed temperature a target voltage margin to maximize the optical power output of the light-emitting device 106 at that temperature can be retrieved by the control module 310.

In another example, at step S506 the control module 310 may calculate the target voltage margin that maximizes the optical power output of the light-emitting device 106 using a formula stored in the memory 312 which uses the sensed temperature as an input.

In another example, at step S506 the control module 310 may trigger an external circuit that regulates the applied voltage to a configured value under the control of the control module 310 to maximize the optical power.

The control module 310 may use the output of an optical sensor (e.g. a photodiode) to support the determination performed at step S506. In particular, a light level sensed by the optical sensor may be used to support the decision of the target voltage margin to maximize the optical power.

At step S508, the control module 310 evaluates the voltage margin received from the voltage readout circuit 302 as an indicator of optical power. In particular, the control module 310 compares the voltage margin received from the voltage readout circuit 302 at step S504, to the target voltage margin determined at step S506, and controls the controllable current source 108 in dependence on the comparison.

If the control module 310 determines at step S508 that the voltage margin received from the voltage readout circuit 302 is greater than the target voltage margin (i.e. larger than needed), the process proceeds to step S510 where the control module 310 sends a control signal, via the interface 308, to increase the current flowing through the light-emitting device 106 to obtain more optical power. This results in the voltage margin (the voltage at the output of the light-emitting device 106) reducing. The control signal may be sent to the controllable current source 108. As noted above, the controllable current source 108 may be a transistor (e.g. a field effect transistor) and the control signal sent from the control module 310 increases the gate voltage on the gate terminal of the transistor to increase current flowing through the light-emitting device 106. It will be appreciated that the control module 310 maximises the optical power output of the light-emitting device 106 by minimizing the voltage margin.

If the control module 310 determines at step S512 that the voltage margin received from the voltage readout circuit 302 is less than the target voltage margin (i.e. lower than needed), the process proceeds to step S514 where the control module 310 sends a control signal, via the interface 308, to decrease the current flowing through the light-emitting device 106. This results in the voltage margin (the voltage at the output of the light-emitting device 106) increasing. The control signal may be sent to the controllable current source 108, which may be a transistor (e.g. a field effect transistor). The control signal sent from the control module 310 decreases the gate voltage on the gate terminal of the transistor to decrease current flowing through the light-emitting device 106. The driver circuit needs a given voltage across the drain and source terminals of the transistor to provide the required current. If the drain source voltage (V_ds), corresponding to the voltage margin referred to above, is not enough, the transistor device works in a different regime in which it is designed for, and stops providing enough current. The control module 310 may then additionally flag this event (either in a register or via an external communication) to indicate that the emitted pulse may have been compromised and may not have enough power.

After the next pulse request is received by the driver die 300, and the next pulse of light is emitted by the light-emitting device 106, the process 500 then loops back to step S502.

In cases where the readout of the voltage at the output of the light-emitting device 106 is slower than a single pulse, a cycle of the above process 500 could be implemented to run for a plurality of pulses, or as long as the voltage readout circuit 302 needs to determine the voltage margin properly.

As part of the process 500, the control module 310 may also control the controllable voltage source 301. The control module 310 may monitor the supply voltage provided by the controllable voltage source 301 and increase the supply voltage until it reaches a maximum. Once at the maximum, if there's still some voltage margin, the control module 510 can increase the current at step S510 by programming more current on the transistor by increasing the gate voltage on the gate terminal of the transistor to increase current flowing through the light-emitting device 106.

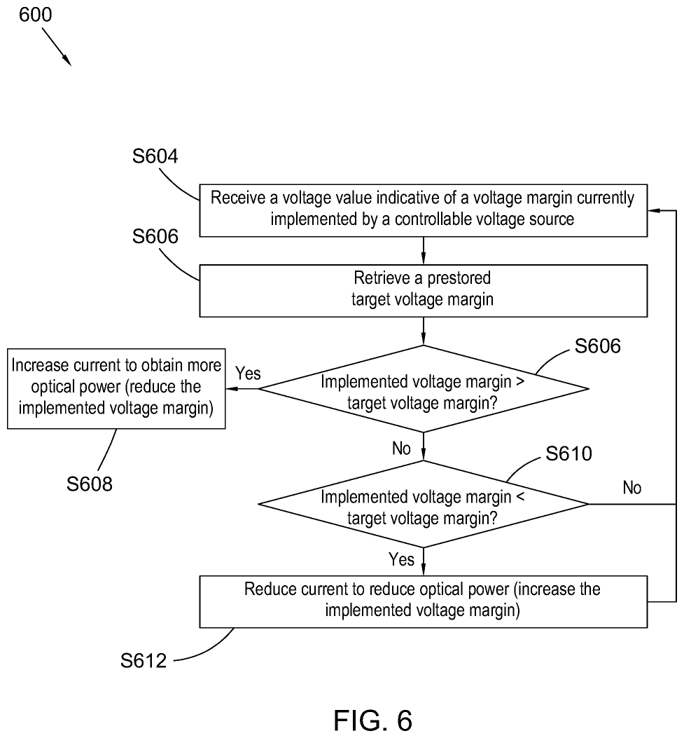

FIG. 6 is a flow chart of an example process 600 that may be implemented by the control module 310 to maximise the optical power output of the light-emitting device 106 without sensing the temperature of the light-emitting device.

Prior to the process 600 being performed a pulse of light may be emitted by the light-emitting device 106.

At step S602, the control module 310 receives a voltage at the output of the light-emitting device 106. That is, the control module 310 receives a voltage indicative of a voltage margin currently implemented by the controllable voltage source 301. The control module 310 receives the voltage margin from the voltage readout circuit 302 via the interface 308.

At step S604, the control module 310 retrieves from memory 312 a prestored target voltage margin i.e. a target voltage for the output of the light-emitting device 106, that is suitable to maximize the optical power output of the light-emitting device 106 without taking into account the actual temperature of the light-emitting device 106. The voltage margin needed to maximize the optical power output of the light-emitting device 106 is not constant over temperature so a ‘safe’ prestored target voltage margin if temperature is not read out.

The process 600 then proceeds to step S606.

Steps S606 and S608 corresponds to steps S508 and S510 described above. Similarly, steps S610 and S612 corresponds to steps S512 and S514 described above.

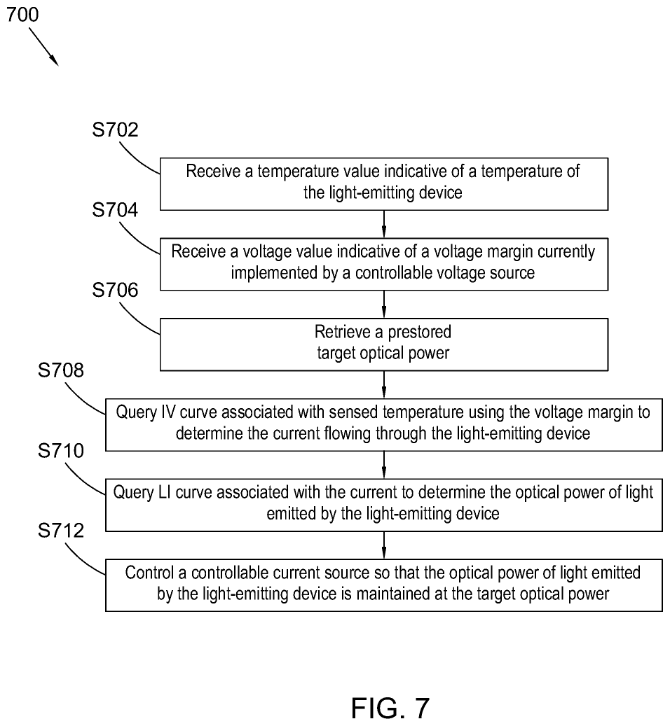

Reference is now made to FIG. 7 which is a flow chart of an example process 700 that may be implemented by the control module 310 to maintain the optical power output of the light-emitting device at a constant power output level.

At step S702, the control module 310 receives a temperature value indicative of a temperature of the light-emitting device 106 that has been sensed by the temperature sensor 304. The control module 310 receives the temperature value from the temperature readout circuit 306 via the interface 308.

At step S704, the control module 310 receives a voltage at the output of the light-emitting device 106. That is, the control module 310 receives a voltage indicative of a voltage margin currently implemented by the controllable voltage source 301. The control module 310 receives the voltage margin from the voltage readout circuit 302 via the interface 308.

At step S706, the control module 310 retrieves from memory 312 a prestored target optical power for light emitted by the light-emitting device 106.

The memory 312 further stores, for a plurality of temperatures, a voltage-current curve associated with the light-emitting device 106 at the respective temperature. The voltage-current curves illustrate how the operating voltage of the light-emitting device 106 varies in dependence with the current flowing through the light-emitting device 106.

The memory 312 further stores, for a plurality of temperatures, a power-current curve associated with the light-emitting device 106 at the respective temperature. The power-current curves illustrate how the optical power of light emitted by the light-emitting device 106 varies in dependence with the current flowing through the light-emitting device 106.

At step S708, the control module 310 retrieves from memory 312 a voltage-current curve defining characteristics of the light-emitting device 106 at the temperature received at step S702. Based on knowledge of the supply voltage provided the controllable voltage source 301, and the voltage margin received at step S704, the control module 310 determines the operating voltage of the light-emitting device 106. The control module 310 then queries the retrieved voltage-current curve using the operating voltage of the light-emitting device 106 to determine the current flowing through the light-emitting device 106.

At step S710, the control module 310 retrieves from memory 312 a power-current curve defining characteristics of the light-emitting device 106 at the temperature received at step S702.

The control module 310 then queries the retrieved power-current curve using the current determined at step S708 to determine the optical power of light emitted by the light-emitting device 106.

At step S712, the control module 310 controls the controllable current source 108 to maintain the optical power of light emitted by the light-emitting device 106 constant.

That is, if the optical power of light emitted by the light-emitting device 106 is less than the prestored target optical power, the control module 310 sends a control signal, via the interface 308, to the controllable current source 108 (e.g. a transistor) to increase the current flowing through the light-emitting device 106 to obtain more optical power. The control signal sent from the control module 310 increases the gate voltage on the gate terminal of the transistor to increase current flowing through the light-emitting device 106.

If the optical power of light emitted by the light-emitting device 106 is greater than the prestored target optical power, the control module 310 sends a control signal, via the interface 308, to the controllable current source 108 (e.g. a transistor) to decrease the current flowing through the light-emitting device 106 to decrease the optical power of the light emitted by the light-emitting device 106. The control signal sent from the control module 310 decreases the gate voltage on the gate terminal of the transistor to decrease current flowing through the light-emitting device 106.

Thus, by knowing the optical power (L) and the voltage (V) as a function of current (I) and temperature (T). For a given setting of power, the control module 310 can control the current (I) by changing the gate voltage as a response of the temperature (T) change to keep the optical power constant.

Any of the embodiments described herein with reference to FIGS. 4-7 may be performed using the arrangement shown in FIG. 3.

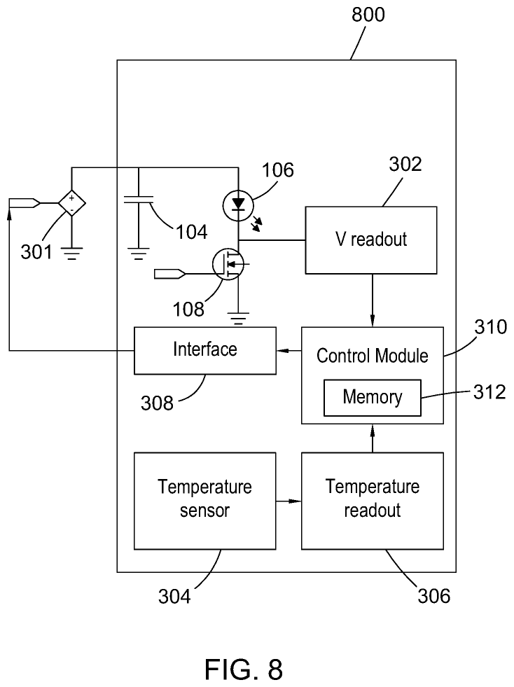

In embodiments described herein, the interface 308, control module 310 and memory 312 may be integrated into the driver die. This is shown by the driver die 800 illustrated in FIG. 8. As shown in FIG. 8, the memory 312 may be integrated into the control module 310. Alternatively, the memory 312 may be separate from the control module 310. In the example implementation shown in FIG. 8, the controllable voltage source 301 remains external to the driver die 800.

Any of the embodiments described herein with reference to FIGS. 4-7 may be performed using the arrangement shown in FIG. 8.

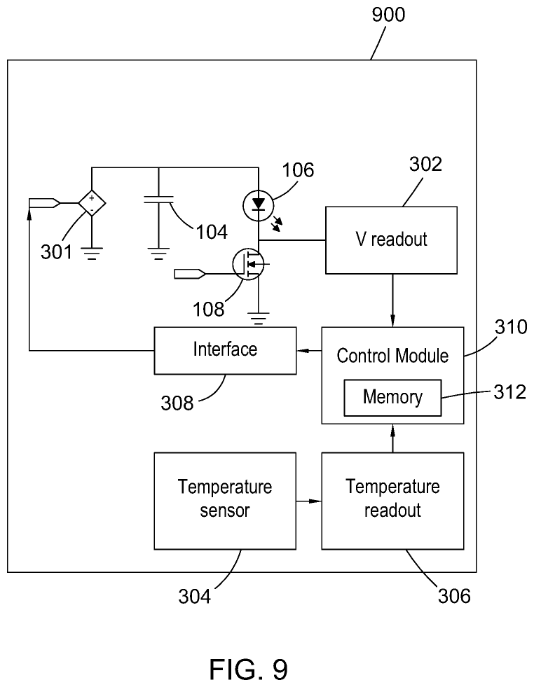

As shown by the driver die 900 illustrated in FIG. 9, the controllable voltage source 301 may also be integrated into the driver die 900 together with the the interface 308, control module 310 and memory 312.

Any of the embodiments described herein with reference to FIGS. 4-7 may be performed using the arrangement shown in FIG. 9.

FIG. 10a illustrates an example voltage readout circuit 302 that may be coupled to the output of the light-emitting device 106. The voltage at the output of the light-emitting device 106 which is supplied as an input to the voltage readout circuit 302 is denoted in FIG. 10a as an input voltage, Vin. The voltage readout circuit 302 is arranged to supply an output voltage denoted in FIG. 10a as Vout. It will be appreciated that the voltage readout circuit 302 shown in FIG. 10a is merely an example and other implementations for the voltage readout circuit 302 are possible.

The example voltage readout circuit 302 shown in FIG. 10a comprises a first diode 1002, a sampling capacitor 1004, a first bias current source 1006, a second diode 1008, a second bias current source 1010 and a filtering capacitor 1012.

Variations in the input voltage, Vin, are too short to be sampled from the outside world. For this reason, a “low-pass” filtering is needed. This filtering is performed by the filtering capacitor 1012.

The first diode 1002 receives the input voltage, Vin, and prevents current to ‘escape’ the main path through the controllable current source 108. The first diode 1002 is coupled to the second diode 1008. The second diode 1008 compensates for the voltage drop on the first diode 1002. The second bias current source 1010 provides a larger bias current than that provided by the first bias current source 1006 to pull up.

FIG. 10b illustrates waveforms associated with the example voltage readout circuit shown in FIG. 10a. In FIG. 10b the CLK waveform corresponds to the control signal supplied by the control module 310 to the controllable voltage source 108. For example, the controllable current source 108 may be a transistor and the control signal CLK may be supplied to a gate of the transistor to thereby control the gate voltage.

As shown in FIG. 10b, square wave pulses of the control signal CLK increase the gate voltage on the gate terminal of the transistor to increase current flowing through the light-emitting device 106 causing the input voltage, Vin, to decrease to a voltage level, Vpeak. There's some time constant associated to the components (lowpass) of the voltage readout circuit 302 shown in FIG. 10a so that the output voltage, Vout, settles at the voltage Vpeak after some cycles, as shown in the FIG. 10b.

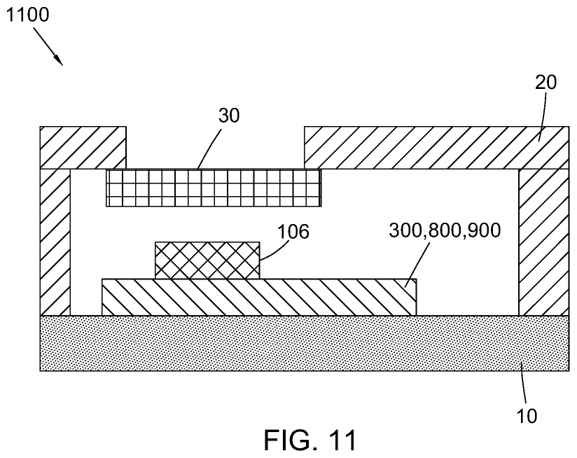

FIG. 11 illustrates an example optoelectronic module 1100 comprising the driver die 300,800,900 that may operate in accordance with any of the embodiments described herein. The driver die is mounted to a substrate 10 which may be a printed circuit board (PCB), a laminate substrate, a lead-frame substrate or the like. The backside of the substrate 10 can include SMT or other contacts for mounting the optoelectronic module 1100, for example, to a printed circuit board.

Various different methods for mounting the driver die to the substrate 10 may be used. The driver die may be mounted to the substrate 10 by gluing (e.g. using a die attach film or a liquid adhesive) or soldering. Electrical connections such as wire bonds and/or contact pads on the backside of the driver die can be provided to couple the driver die to contact pads on the substrate 10.

The optoelectronic module 100 further comprises the light-emitting device 106. In the example shown in FIG. 11, the light-emitting device 106 is mounted to the upper surface of the driver die. Various different methods for mounting the light-emitting device 106 to the driver die may be used. The light-emitting device 106 may be mounted to the driver die by gluing with a conductive adhesive or soldering. Electrical connections such as wire bonds and/or contact pads on the backside of the light-emitting device 106 can be provided to couple the light-emitting device 106 to contact pads on the driver die. As noted above, alternatively the light-emitting device 106 may be integrated into the driver die or external to the driver die and mounted to the substrate 10.

A spacer 20 is mounted to the upper surface of the driver die (e.g. using an adhesive). The spacer 20 encloses the light-emitting device 106. Expressed another way, the spacer laterally surrounds the light-emitting device 106. The spacer 20 forms a cavity filled with air.

An optical element 30 is mounted to the spacer 20. The optical element 30 is transmissive of wavelengths of light emitted by the light-emitting device 106.

The optical element 30 may be coupled to a transparent substrate. The optical element 30 may comprise, for example, one or more lenses, a microlens array, and/or a diffuser. The transparent substrate preferably comprises glass. However, other materials are suitable, for example plastic. In some embodiments, the substrate can comprise SiO₂ or “display” glass, such as Schott D263T-ECO or Borofloat 33, Dow-Corning Eagle 2000.

The optoelectronic module 1100 may be incorporated into a computing device such as a mobile phone, laptop, tablet, drone, robot, or wearable device etc.

Although the disclosure has been described in terms of preferred embodiments as set forth above, it should be understood that these embodiments are illustrative only and that the claims are not limited to those embodiments. Those skilled in the art will be able to make modifications and alternatives in view of the disclosure, which are contemplated as falling within the scope of the appended claims. Each feature disclosed or illustrated in the present specification may be incorporated in any embodiments, whether alone or in any appropriate combination with any other feature disclosed or illustrated herein.

### REFERENCE NUMERALS

100 driver circuit
102 fixed laser diode driver voltage supply
104 capacitor
106 light-emitting device
108 controllable current source
200 example data
202 room temperature
300 driver die
301 controllable voltage source
302 voltage readout circuit
304 temperature sensor
306 temperature readout circuit
308 interface
310 control module
312 memory
800 driver die
900 driver die
1002 first diode
1004 sampling capacitor
1006 first bias current source
1008 second diode
1010 second bias current source
1012 filtering capacitor
1100 optoelectronic module
10 substrate
20 spacer
30 optical element

1. An optical apparatus comprising:
a light-emitting device coupled to a controllable voltage supply configured to provide a supply voltage to the light-emitting device;
a temperature sensor arranged to sense a temperature of the light-emitting device;
a driver die comprising a driver circuit for driving the light-emitting device; and
a control module configured to:
receive a voltage at the output of the light-emitting device;
determine a target voltage that is to be provided at the output of the light-emitting device, wherein the control module is configured to determine the target voltage based on said temperature; and
output a control signal to control the output of the light-emitting device to be at the target voltage in dependence on the voltage at the output of the light-emitting device.

2. The apparatus of claim 1, wherein the control module is configured to:
compare the voltage at the output of the light-emitting device to the target voltage; and
output the control signal to the controllable voltage supply to control the supply voltage in dependence on the comparison.

3. The apparatus of claim 1, wherein:
if the voltage at the output of the light-emitting device is greater than the target voltage, the control module is configured to output the control signal to the controllable voltage supply to decrease the supply voltage; and
if the voltage at the output of the light-emitting device is less than the target voltage, the control module is configured to output the control signal to the controllable voltage supply to increase the supply voltage.

4. The apparatus of claim 1, wherein the target voltage minimizes power loss of the driver die.

5. The apparatus of claim 1, wherein the control module is configured to:
compare the voltage at the output of the light-emitting device to the target voltage; and
output the control signal to a current source of the driver circuit, to control an amount of current flowing through the light-emitting device in dependence on the comparison.

6. The apparatus of claim 5, wherein the driver die comprises a controllable current source and:
if the voltage at the output of the light-emitting device is greater than the target voltage, the control module is configured to output the control signal to the controllable current source increase current flowing through the light-emitting device; and
if the voltage at the output of the light-emitting device is less than the target voltage, the control module is configured to output the control signal to the controllable current source to decrease current flowing through the light-emitting device.

7. The apparatus of claim 5, wherein the target voltage maximizes the optical power of light emitted by the light-emitting device.

8. The apparatus of claim 1, wherein the control module is configured to:
retrieve from memory a voltage-current curve associated with the temperature;
use the voltage at the output of the light-emitting device and the voltage-current curve to determine the current flowing through the light-emitting device;
retrieve from memory a power-current curve associated with the temperature;
use the current flowing through the light-emitting device and the power-current curve to determine the optical power of light emitted by the light-emitting device; and
control a controllable current source of the driver die to maintain the optical power of light emitted by the light-emitting device constant.

9. The apparatus of claim 1, wherein the light-emitting device is integrated into the driver die.

10. The apparatus of claim 1, wherein the light-emitting device is external to the driver die.

11. The apparatus of claim 10, wherein the light-emitting device is mounted to an upper surface of the driver die.

12. The apparatus of claim 1, wherein the control module is external to the driver die.

13. The apparatus of claim 1, wherein the control module is integrated into the driver die.

14. The apparatus of claim 1, wherein the driver die comprises a voltage readout circuit coupled to the light-emitting device, the voltage readout circuit configured to detect and supply the voltage at the output of the light-emitting device to the control module.

15. The apparatus of claim 1, wherein the light-emitting device comprises a vertical cavity surface emitting laser.

16. An optoelectronic module comprising:
the apparatus of claim 1;
a substrate, wherein the driver die is mounted to an upper surface of the substrate;
a spacer mounted to the upper surface of the substrate, the spacer laterally surrounding the light-emitting device; and
an optical element mounted to the spacer, the optical element transparent to light emitted by the light-emitting device.
